(19) United States
(12) Patent Application Publication
(10) Pub. No.: US 2009/0146604 A1
(43) Pub. Date: Jun. 11, 2009

(54) COMPLEX LITHIUM SECONDARY BATTERY AND ELECTRONIC DEVICE EMPLOYING THE SAME

(75) Inventors: Jae-man Choi, Hwaseong-si (KR); Han-su Kim, Seoul (KR); Moon-seok Kwon, Hwaseong-si (KR); Seok-gwang Doo, Seoul (KR)

Correspondence Address: STEIN MCEWEN, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/147,550

(22) Filed: Jun. 27, 2008

(30) Foreign Application Priority Data
Dec. 11, 2007 (KR) 2007-128269

(51) Int. Cl. H01M 10/46; H01M 4/24; H02J 7/32; H01L 31/04

(52) U.S. Cl. 320/101; 429/209; 136/252

(57) ABSTRACT

Provided is a complex lithium secondary battery that includes a dye-sensitized solar cell unit and a lithium secondary battery unit, wherein the dye-sensitized solar cell unit and the lithium secondary battery unit share a common anode layer. The complex lithium secondary battery is rechargeable using solar energy, as an alternative power source to when there is no power source for recharging the complex lithium secondary battery, can be bendable, and has a simple structure.

### CROSS-REFERENCE TO RELATED APPLICATIONS

This application claims the benefit of Korean Patent Application No. 2007-128269, filed on Dec. 11, 2007, in the Korean Intellectual Property Office, the disclosure of which is incorporated herein in its entirety by reference.

### BACKGROUND OF THE INVENTION

1. Field of the Invention

The present invention relates to a complex lithium secondary battery, and more particularly, to a complex lithium secondary battery that is rechargeable using solar energy as a power source when there is no power source for charging the complex lithium secondary battery, is bendable, and has a simple structure.

2. Description of the Related Art

As mobile electronic devices such as video cameras, mobile phones, or computer notebooks are becoming lightweight and highly functional, many studies are being conducted on batteries used for driving such mobile electronic devices. In particular, research and development has been actively conducted on a rechargeable lithium secondary battery since the rechargeable lithium secondary battery has advantages in that an energy density is three times greater than that of a lead-acid battery, a Ni—Cd cell, a Ni-hydrogen cell, and a Ni—Zn cell and can be rapidly chargeable.

Mobile electronic devices that use the rechargeable lithium secondary battery expand from cassette tape players, compact disc players, MP3 players, and mobile phones to multi-media players that can realize moving images, and it is anticipated that such mobile electronic devices can be developed into bendable or wearable mobile electronic devices using a flexible display device. In order to drive these mobile electronic devices, the development of a suitable power source is required.

However, the rechargeable lithium secondary battery has a drawback in that its battery cells can be recharged only when there is a power source. Thus, a concept of a secondary battery that can be recharged regardless of the location has been proposed such that the secondary battery is chargeable using sunlight even when the electronic devices are not being used,

FIG. 1 is a cross-sectional view showing a concept of a conventional dye-sensitized solar cell 10. Referring to FIG. 1, the conventional dye-sensitized solar cell 10 includes an photoanode layer 11 that includes a transparent electrode 11a, a metal oxide 11b, and a dye 11c adsorbed to the metal oxide 11b, a solar cell electrolyte layer 12, and a counter electrode 13. The dye-sensitized solar cell 10 is operated based on a principle that incident light that has entered through the transparent electrode 11a generates electron-hole pairs by exciting molecules of the dye 11c from a ground state to an excited state, and the excited electrons are injected into a conduction band of the metal oxide 11b, and thus, an electromotive force is formed by collecting the electrons.

### SUMMARY OF THE INVENTION

To address the above and/or other problems, the present invention provides a complex lithium secondary battery that is chargeable using solar energy as an alternative power source when there is no additional power source for charging the complex lithium secondary battery, can be bendable, and has a simple structure.

The present invention also provides an electronic apparatus that employs the complex lithium secondary battery.

According to an aspect of the present invention, there is provided a complex lithium secondary battery comprising: a dye-sensitized solar cell unit; and a lithium secondary battery unit, wherein the dye-sensitized solar cell unit and the lithium secondary battery unit share a common anode layer.

The dye-sensitized solar cell unit may comprise a transparent conductive material layer; a reducing catalyst layer; a solar cell electrolyte layer that reduces oxidized dye molecules; a transition metal oxide semiconductor layer in which a dye is adsorbed to emit electrons when the dye absorbs light; and the common anode layer that can collect electrons from the transition metal oxide semiconductor layer.

The complex lithium secondary battery may further comprise a boost circuit to boost an electromotive force generated from the dye-sensitized solar cell unit to a voltage greater than an operation voltage of the lithium secondary battery unit.

According to an aspect of the present invention, there is provided an electronic apparatus comprising the complex lithium secondary battery described above.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a cross-sectional view showing a conventional dye-sensitized solar cell; and

FIG. 2 is a cross-sectional view showing a concept of a complex lithium secondary battery, according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

The present invention will now be described more fully with reference to the accompanying drawings, in which exemplary embodiments of the invention are shown. The present invention may, however, be embodied in many different forms and should not be construed as being limited to the embodiments set forth herein; rather, these embodiments are provided so that this disclosure will be thorough and complete, and will fully convey the concept of the invention to one skilled in the art. Like reference numerals in the drawings denote like elements. In the drawings, various elements and regions are schematically drawn for clarity. Thus, the present invention is not limited to the relative size or gaps shown in the drawings. It will also be understood that when a layer is referred to as being “on” another layer or substrate, it can be directly on the other layer or substrate, or intervening layers may also be present.

The present invention provides a complex lithium secondary battery in which a lithium secondary battery and a solar cell are combined. That is, the complex lithium secondary battery according to the present invention includes a dye-sensitized solar cell unit and a lithium secondary battery unit which are electrically connected to each other by sharing a common anode layer.

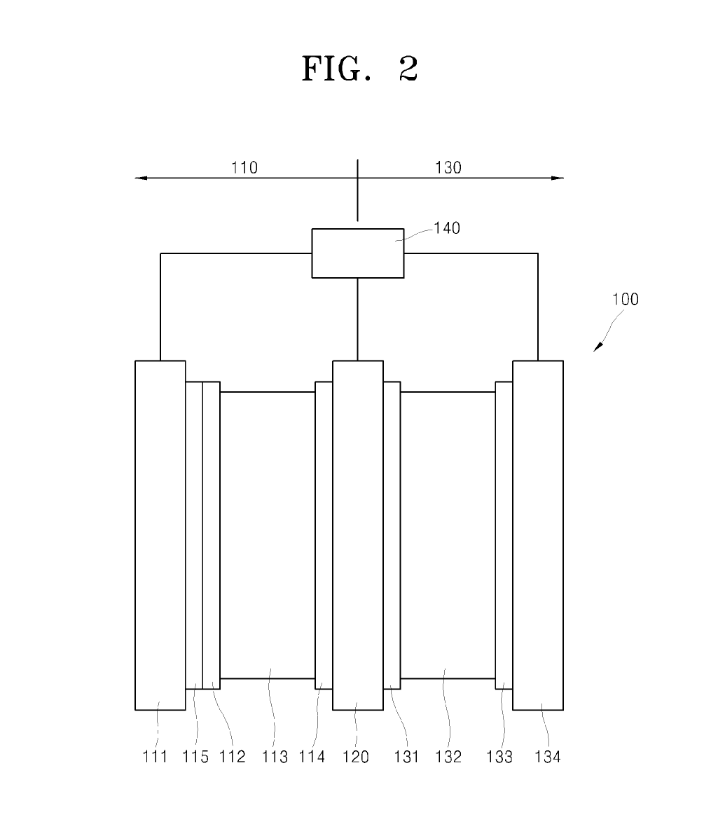

FIG. 2 is a cross-sectional view showing a concept of a complex lithium secondary battery 100 according to an embodiment of the present invention. Referring to FIG. 2, the complex lithium secondary battery 100 includes a dye-sensitized solar cell unit 110 and a lithium secondary battery unit 130 that have a common anode layer 120 interposed therebetween. The common anode layer 120 corresponds to an photoanode layer in view from the dye-sensitized solar cell unit 110, and corresponds to an anode current collector in view from the lithium secondary battery unit 130. The common anode layer 120 can be formed as a single layer using a conductive material that includes at least one selected from the group consisting of Cu, Ti, Ni, and stainless steel.

In particular, the dye-sensitized solar cell unit 110 can be a stack of layers in which a transparent conductive material layer 111, a reducing catalyst layer 112, a solar cell electrolyte layer 113 that reduces oxidized dye molecules, a transition metal oxide semiconductor layer 114 in which a dye that can emit electrons by absorbing light is adsorbed, and the common anode layer 120 that can collect electrons emitted from the transition metal semiconductor layer 114.

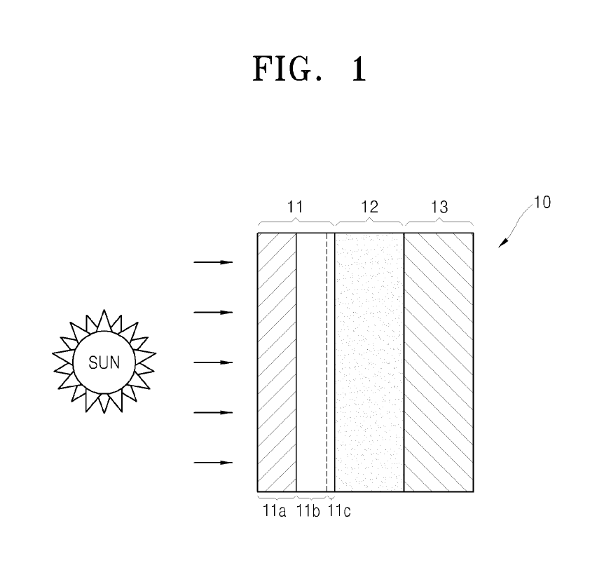

In the foregoing embodiment, in order for the dye-sensitized solar cell unit 110 and the lithium secondary battery unit 130 to share the common anode layer 120, the dye-sensitized solar cell unit 110, unlike the conventional dye-sensitized solar cell 10 that uses absorbed light incident on the photoanode layer 11 as shown in FIG. 1, can absorb light radiated from the outside through the transparent conductive material layer 111, which corresponds to the a counter electrode 13 of FIG. 1.

The transparent conductive material layer 111 corresponds to a cathode of the dye-sensitized solar cell unit 110, and sunlight is radiated into the dye-sensitized solar cell unit 110 through the transparent conductive material layer 111. In the present embodiment, the transparent conductive material layer 111 can be formed of, for example, a transparent and electrically conductive material or formed by coating a conductive material on a transparent material. The transparent and conductive material of the transparent conductive material layer 111 can be a conductive polymer material, for example, a polyaniline based, a polyacetylene based, a polypyrrole based, or a polythiophene based polymer. When a conductive material is coated on a transparent material to form the transparent conductive material layer 111, the transparent material can be, for example, a transparent inorganic substrate such as quartz or glass, or a transparent polymer substrate such as polyethylene terephthalate (PET), polyethylene naphthalate, polycarbonate, polystyrene, polypropylene, etc. Also, the conductive material that can be coated on the transparent material to form the transparent conductive material layer 111 can be indium tin oxide (ITO), indium zinc oxide (IZO), fluorine doped tin oxide (FTO), or ZnO—Ga₂O₃, ZnO—Al₂O₃, SnO₂—Sb₂O₃, etc., however, the materials are not limited thereto.

The reducing catalyst layer 112 can be, for example, a Pt catalyst layer in which Pt used as the catalyst is thinly coated so as to transmit visible light. In order to form the thinly coated Pt catalyst layer, for example, a sputtering method can be used, so that the Pt catalyst layer can have a thickness of, for example, 1 nm to 100 nm.

Alternatively, in order to increase the electrical conductivity of the cathode side of the dye-sensitized solar cell unit 110, a transparent electrode layer 115 can further be formed between the transparent conductive material layer 111 and the reducing catalyst layer 112, by coating a transparent conductive oxide such as ITO, FTO, ZnO, or SnO₂ on the transparent conductive material layer 111.

The solar cell electrolyte layer 113 is a layer in which an oxidation-reduction reaction is practically performed on the reducing catalyst layer 112, and can include an imidazole based compound and iodine, that is, for example, iodine based oxidation-reduction electrolyte I⁻/I₃⁻. The solar cell electrolyte layer 113 can be a solution layer in which 0.70 M 1-vinyl-3-methyl-imidazolium iodide, 0.10 M LiI, 40 mM I₂, 0.125 M 4-tert-butylpyridine are dissolved in 3-methoxypropionitrile. Alternatively, the solar cell electrolyte layer 113 can include organic molecules that can form an insulating protective film by self-assembling on the metal oxide through a selective chemical reaction with a metal oxide, as will be described later.

The transition metal oxide semiconductor layer 114 comprises a metal oxide and a dye adsorbed to a surface of the metal oxide. In order to obtain high efficiency, it is necessary for the transition metal oxide semiconductor layer 114 to absorb sunlight energy as much as possible. Thus, the surface area of the transition metal oxide semiconductor layer 114 is maximized by using a porous metal oxide as the metal oxide and onto which a dye is adsorbed to the surface of the porous metal oxide. The transition metal oxide semiconductor layer 114 is formed to a thickness of, for example, 5 to 10 μm, and may be a crystalline metal oxide layer having pores with a size of 20 to 2000 nm and a porosity of 40 to 60%. The metal oxide that constitutes the transition metal oxide semiconductor layer 114 can have a diameter of 15 to 25 nm, and can be TiO₂, SnO₂, ZnO, WO₃, Nb₂O₅, or TiSrO₃, for example, an anatase-type TiO₂.

The dye coated on the metal oxide can be any dye that is used in the solar cell field, and if the dye has a charge separation function and is photosensitive, there is no particular limitation in selecting the dye. The dye can be, for example, a ruthenium complex, a xanthine based dye such as rhodamine B, Rose Bengal, eosin, or erythrosine; a cyanine based dye such as quinocyanine or cryptocyanine; a basic dye such as phenosafranine, capri blue, thiosine, or methylene blue; a porphyrin based compound such as chlorophyll, zinc porphyrin, or magnesium porphyrin; an azo dye; a phthalocyanine compound; a ruthenium tris-bipyridyl based complex compound; an anthraquinone based dye; a polycyclic quinone based dye; and a single or a mixture of at least two of the above materials can be used as the dye. In particular, the ruthenium complex can be RuL₂(SCN)₂, RuL₂(H₂O)₂, RuL₃, or RuL₂ wherein L can be 2,2′-bipyridyl-4,4′-dicarboxylate.

A method of coating the dye on the metal oxide can be achieved such that, for example, after forming the metal oxide in a film shape, the film is soaked in a dye solution for more than 24 hours, and then, the film is dried under an inert gas atmosphere.

The common anode layer 120 can perform as an photoanode layer of the dye-sensitized solar cell unit 110 through the transition metal oxide semiconductor layer 114, in view from the dye-sensitized solar cell unit 110. Also, the common anode layer 120 can perform as a anode current collector of the lithium secondary battery unit 130 in view from the lithium secondary battery unit 130 formed on an opposite side to the dye-sensitized solar cell unit 110 since the common anode layer 120 contacts an anode active material layer 131 of the lithium secondary battery unit 130.

The lithium secondary battery unit 130 largely includes: an cathode active material layer 133 to which lithium ions are occluded when the lithium secondary battery is discharged; the anode active material layer 131 to which lithium ions are occluded when the lithium secondary battery is charged; a lithium battery electrolyte layer 132 that is disposed between the cathode active material layer 133 and the anode active material layer 131, in which a lithium salt is dissolved in a non-aqueous solvent, and where an oxidation/reduction reaction occurs; and an cathode current collector layer 134 formed on the cathode active material layer 133.

The cathode current collector layer 134 can be formed as a aluminum thin film or a conductive polymer film which is bendable (hereinafter respectively referred to as a ‘bendable aluminum thin film’ or a ‘bendable conductive polymer film’).

The cathode active material layer 133 can be formed of a Li—Co based composite oxide such as LiCoO₂, a Li—Ni based composite oxide such as LiNiO₂, a Li—Mn based composite oxide such as LiMn₂O₄ or LiMnO₂, a Li—Cr based composite oxide such as Li₂Cr₂O₇ or Li₂CrO₄, a Li—Fe based composite oxide such as LiFeO₂, and a Li—V based composite oxide.

The anode active material layer 131 can be formed of a Li—Ti based composite oxide such as Li₄Ti₅O₁₂, a transition metal oxide such as SnO₂, In₂O₃, or Sb₂O₃, and a carbon group material such as graphite, hard carbon, acetylene black, or carbon black.

Alternatively, in order to increase conductivity of the oxide particles of the anode active material layer 131 and the cathode active material layer 133, the anode active material layer 131 and the cathode active material layer 133 can further include a conductive material such as acetylene black, carbon black, graphite, carbon fiber, or a carbon nanotube.

Alternatively, after forming the cathode current collector layer 134 as a bendable aluminum thin film or a bendable conductive polymer film, the bendable lithium secondary battery unit 130 can be formed by printing or depositing the cathode active material layer 133, the lithium battery electrolyte layer 132, and the anode active material layer 131, each in a thin film shape and having a thickness of 1 mm or less, sequentially on the cathode current collector layer 134. In particular, the conductive polymer film of the cathode current collector layer 134 can be a film formed of a polymer of a polyaniline based, a polyacetylene based, a polypyrrole based, or a polythiophene based polymer, or can be formed by coating a conductive material on a transparent material as for the transparent conductive material layer 111 described above and the method of coating of the conductive material on the transparent material has already been described above, and thus, a detailed description thereof will not be repeated.

Alternatively, the complex lithium secondary battery 100 according to an embodiment of the present invention can further include a boost circuit 140 to boost an electromotive force generated by the dye-sensitized solar cell unit 110 so as to charge the lithium secondary battery unit 130. The electromotive force that can be obtained through a photoelectric conversion using a dye-sensitized solar cell that has been developed up to now may not be suitable for directly charging a lithium secondary battery. However, the electrical energy can be supplied to the lithium secondary battery unit 130 by boosting the electromotive force generated in the dye-sensitized solar cell unit 110 to a voltage greater than an operation voltage of the lithium secondary battery unit 130, via the boost circuit 140. The operation voltage of the lithium secondary battery unit 130 can be, for example, 2.2 to 4.2 V, and the boost circuit 140 can boost the electromotive force generated in the dye-sensitized solar cell unit 110 to a range of 2.1 to 5.0V, preferably 2.5 to 5.0V.

A lithium secondary battery generally includes a protective circuit (not shown) that can prevent its overcharge or over-discharge. A charge circuit (not shown) may be disposed between the protective circuit and the boost circuit 140 such that the charge circuit appropriately controls an output voltage from the boost circuit 140, and thus, charge the lithium secondary battery unit 130.

An operation principle of the complex lithium secondary battery 100 according to an embodiment of the present invention will now be described.

First, the operation of the dye-sensitized solar cell unit 110 will now be described. Light that has transmitted through the transparent conductive material layer 111 and the reducing catalyst layer 112 reaches the transition metal oxide semiconductor layer 114 through the solar cell electrolyte layer 113. Due to the light, electrons of dye molecules, which are adsorbed to the transition metal oxide semiconductor layer 114, are excited, and the electrons are injected to a conduction band of a metal oxide. Then, the electrons are transmitted to the lithium secondary battery unit 130 through the common anode layer 120 that is adjacent to the transition metal oxide semiconductor layer 114. At this point, the electrons can be transmitted to the lithium secondary battery unit 130 through the boost circuit 140.

The transparent conductive material layer 111 receives the electrons from an cathode of the lithium secondary battery unit 130 or the boost circuit 140, and transmits the electrons to the solar cell electrolyte layer 113. At this point, the reducing catalyst layer 112 promotes a reduction reaction so that the electrolyte of the solar cell electrolyte layer 113 can be readily reduced. If iodine electrolyte is used in the solar cell electrolyte layer 113, the reduction reaction occurs as I₃⁻+2e⁻→3I⁻.

Then, dye molecules that adsorbed to the metal oxide in the transition metal oxide semiconductor layer 114 receive electrons from the solar cell electrolyte layer 113 due to an oxidation reaction occurring in the solar cell electrolyte layer 113, and supplement the electrons that are emitted to the outside through the metal oxide of the transition metal oxide semiconductor layer 114 and the common anode layer 120, and thus, the operation process of the dye-sensitized solar cell unit 110 is completed.

Next, the operation of the lithium secondary battery unit 130 will now be described. A discharge phenomenon occurs in the lithium secondary battery unit 130 when power is used by connecting the lithium secondary battery unit 130 to an external circuit. At this point, lithium ions move to a cathode from an anode through a lithium ion conductive electrolyte, and electrons are moved in a counter direction of the lithium ions through an external circuit. When the lithium secondary battery is charged, the lithium ions and the electrons move in counter directions to the directions of discharge.

The present invention provides an electronic apparatus that includes the complex lithium secondary battery described above, and such complex lithium secondary battery can be used in, for example, mobile phones, MP3 players, portable multimedia players (PMPs), personal digital assistant (PDAs), or electronic dictionaries, and the applications of the complex lithium secondary battery are not limited thereto.

According to the present invention, provided is a complex lithium secondary battery that can be rechargeable using solar energy as an alternative power source to when there is no power source for recharging the complex lithium secondary battery, can be bendable, and has a simple structure.

While the present invention has been particularly shown and described with reference to exemplary embodiments thereof, it will be understood by one of ordinary skill in the art that various changes in form and details may be made therein without departing from the spirit and scope of the present invention as defined by the following claims.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A complex lithium secondary battery comprising:
a dye-sensitized solar cell unit; and
a lithium secondary battery unit,
wherein the dye-sensitized solar cell unit and the lithium secondary battery unit share a common anode layer.

2. The complex lithium secondary battery of claim 1, wherein the dye-sensitized solar cell unit comprising:
a transparent conductive material layer;
a reducing catalyst layer;
a solar cell electrolyte layer that reduces oxidized dye molecules;
a transition metal oxide semiconductor layer in which a dye is adsorbed to emit electrons when the dye absorbs light; and
the common anode layer that can collect electrons from the transition metal oxide semiconductor layer.

3. The complex lithium secondary battery of claim 1, further comprising a boost circuit to boost an electromotive force generated from the dye-sensitized solar cell unit to a voltage greater than an operation voltage of the lithium secondary battery unit.

4. The complex lithium secondary battery of claim 1, wherein the common anode layer is a conductive material that comprises at least one selected from the group consisting of Cu, Ti, Ni, and stainless steel.

5. The complex lithium secondary battery of claim 1, wherein the lithium secondary battery unit comprises:
an anode active material layer, a cathode active material layer, a lithium battery electrolyte layer that is disposed between the anode active material layer and the cathode active material layer and in which a lithium salt is dissolved in a non-aqueous solvent;
a cathode current collector; and
the common anode layer.

6. The complex lithium secondary battery of claim 2, wherein the transparent conductive material layer is formed by coating at least one material selected from the group consisting of indium tin oxide (ITO), indium zinc oxide (IZO), fluorine doped tin oxide (FTO), ZnO—Ga₂O₃, ZnO—Al₂O₃, and SnO₂—Sb₂O₃ on at least one material selected from the group consisting of quartz, glass, polyethylene terephthalate (PET), polyethylene naphthalate, polycarbonate, polystyrene, and polypropylene.

7. The complex lithium secondary battery of claim 2, wherein the transition metal oxide semiconductor layer is formed by coating at least one dye selected from the group consisting of a ruthenium complex; a xanthine based dye of rhodamine B, Rose Bengal, eosin, and erythrosine; a cyanine based dye of quinocyanine and cryptocyanine; a basic dye of phenosafranine, capri blue, thiosine, and methylene blue; a porphyrin based compound of chlorophyll, zinc porphyrin, and magnesium porphyrin; an azo dye; a phthalocyanine compound; a ruthenium tris-bipyridyl based complex compound; an anthraquinone based dye; and a polycyclic quinone based dye on at least one metal oxide selected from the group consisting of TiO₂, SnO₂, ZnO, WO₃, Nb₂O₅, and TiSrO₃.

8. The complex lithium secondary battery of claim 5, wherein the cathode current collector is formed of an aluminum thin film or a conductive polymer film.

9. An electronic apparatus comprising the complex lithium secondary battery of claim 1.
